(19) United States
(12) Patent Application Publication
(10) Pub. No.: US 2026/0349656 A1
(43) Pub. Date: Nov. 5, 2026

(54) SYSTEMS AND METHODS FOR ANALOG MULTIPLIERS

(71) Applicant: Northrop Grumman Systems Corporation, Falls Church, VA (US)

(72) Inventors: Bouchaib Cherif, Yorktown Heights, NY (US); Philippe Pouliquen, Baltimore, MD (US)

(21) Appl. No.: 19/194,783

(22) Filed: Apr. 30, 2025

(51) Int. Cl. G06F 7/53; H03K 19/173

(52) U.S. Cl. CPC G06F 7/53; H03K 19/1737

(57) ABSTRACT

A four-quadrant analog multiplier can include first and second multipliers. The first multiplier can include a first plurality of PFETs and a first plurality of NFETs. The first multiplier can be configured to receive at most four voltages and configured to output, based on the at most four voltages, a first output current. The second multiplier can include a second plurality of PFETs and a second plurality of NFETs. The second multiplier can be configured to receive the at most four voltages and configured to output, based on the at most four voltages, a second output current. The four-quadrant analog multiplier may generate a difference between the first output current and the second output current.

### FIELD

The present disclosure relates generally to analog multipliers, and more particularly to multipliers using a plurality of branches of transistors.

### BACKGROUND

Analog transistor multipliers can be used in various signal processing applications. Such multipliers may use non-linear properties of transistors to perform analog multiplication and may use transfer characteristics of bipolar junction transistors (BJTs) or field-effect transistors (FETs). Traditional designs for analog multipliers, such as Gilbert cells, achieve multiplication by combining differential amplifier configurations with precise biasing schemes, but conventional designs often face challenges such as limited linearity, increased power consumption, and wasted power generation. Existing multipliers are insufficient in many ways that are addressed by example embodiments described below.

### SUMMARY

Aspects and advantages of the present disclosure will be set forth in part in the following description, or may be obvious from the description, or may be learned through practice of the present disclosure.

In an aspect, the present disclosure is directed to a four-quadrant analog multiplier comprising: a first branch configured to multiply voltage values representing a positive x-value, relative to an x-reference voltage, and a positive y-value, relative to a y-reference voltage, to obtain a first branch current; a second branch configured to multiply voltage values representing the positive x-value, relative to the x-reference voltage, and a negative y-value, relative to the y-reference voltage, to obtain a second branch current; a third branch configured to multiply voltage values representing a negative x-value, relative to the x-reference voltage, and the negative y-value, relative to the y-reference voltage, to obtain a third branch current; and a fourth branch configured to multiply voltage values representing the negative x-value, relative to the x-reference voltage, and the positive y-value, relative to the y-reference voltage, to obtain a fourth branch current; wherein the four-quadrant analog multiplier is configured to summate the first, second, third, and fourth currents to generate a first output current; and wherein at least one of the first, second, third, or fourth branches comprises a PFET, and wherein at least one of the first, second, third, or fourth branches comprises an NFET.

In an aspect, the present disclosure is directed to an analog multiplier comprising: a first multiplier comprising a first plurality of PFETs and a first plurality of NFETs, the first multiplier configured to receive at least four voltages and configured to output, based on the at least four voltages, a first output current; and a second multiplier comprising a second plurality of PFETs and a second plurality of NFETs, the second multiplier configured to receive the at least four voltages and configured to output, based on the at least four voltages, a second output current.

In an aspect, the present disclosure is directed to an analog multiplier comprising: a first multiplier configured to output a first output current, the first multiplier comprising a first plurality of branches each configured to generate respective branch currents of a first plurality of branch currents, the first multiplier configured to summate the first plurality of branch currents to generate the first output current; and a second multiplier configured to output a second output current, the second multiplier comprising a second plurality of branches each configured to generate respective branch currents of a second plurality of branch currents, the second multiplier configured to summate the second plurality of currents to generate the second output current.

### BRIEF DESCRIPTION OF THE DRAWINGS

A full and enabling disclosure of the present disclosure directed to one of ordinary skill in the art, is set forth in the specification, which makes reference to the appended figures.

FIG. 1 shows an example analog multiplier, according to some embodiments.

FIG. 2 shows a graph of the output current Iₒᵤₜ of the analog multiplier shown in FIG. 1, at different Vₓ values for five different V_{y} values.

FIG. 3 shows another example analog multiplier, according to some embodiments.

FIG. 4 shows a graph of output current I_{out_p}−I_{out_n} of the analog multiplier shown in FIG. 3, at different Vₓ values for five different V_{y} values.

FIG. 5 shows a graph of output current L_{out_p}−I_{out_n} of the analog multiplier shown in FIG. 3, at different Vₓ values for five different V_{y} values, with a 90 mV common-mode voltage difference.

FIG. 6 shows a graph of output current I_{out_p}−I_{out_n} of the analog multiplier shown in FIG. 3, at different Vₓ values for five different V_{y} values, with a 4× transistor ratio.

### DETAILED DESCRIPTION

Reference now will be made in detail to embodiments of the disclosure, one or more examples of which are illustrated in the drawings. Each example is provided by way of explanation of the disclosure, not limitation of the disclosure. In fact, it will be apparent to those skilled in the art that various modifications and variations can be made in the present disclosure without departing from the scope or spirit of the disclosure. For instance, features illustrated or described as part of one embodiment can be used with another embodiment to yield a still further embodiment. Thus, it is intended that the present disclosure covers such modifications and variations as come within the scope of the appended claims and their equivalents.

Analog multipliers are valuable components in signal processing and communication systems. Multipliers can enable functions such as amplitude modulation, frequency mixing, and/or phase detection. These circuits can benefit from nonlinear properties of transistor to achieve multiplication.

Modern designs often rely on current mirror architectures and are often employed to facilitate signal manipulation and biasing in multiplier circuits. However, while multipliers using current mirror have some benefits, they also have drawbacks. The use of current mirrors can introduce additional power consumption, increased complexity, and/or potential mismatches due to process variations. These factors can degrade the linearity and precision of the multiplier output, which is problematic in applications requiring high fidelity and low distortion. Additionally or alternatively, at high frequencies and/or low-power regimes, parasitic effects and response times of current mirrors may limit overall circuit performance.

Embodiments described herein can use architectures that achieve reliable results without the use of current mirrors. For example, some embodiments include a plurality of branches of transistors to replicate the needed currents instead of copying currents with current mirrors. In embodiments without current mirrors, power dissipation can be reduced, response time improved, power that is consumed can be better conserved, and/or process-induced mismatches may be mitigated.

Embodiments described herein can improve the functionality and efficiency of conventional wide-range CMOS analog multipliers. Conventional multipliers subtract differential output currents through current mirrors, producing a single-ended, bidirectional current output with a mean of zero. However, in certain circumstances such as when differential output currents are needed, the inherent bias currents that are required for the multiplier's operation may become a part of the output current. The inclusion of the inherent bias currents can weaken the performance of subsequent circuits, such as current buffers, since the output current may be significantly smaller than the bias current.

Conventionally, this problem is mitigated by adding an extra bias currents to the outputs, effectively neutralizing the multiplier's bias currents and directing them towards the power supply. However, to address this challenge, embodiments described herein can utilize the existing multiplier bias current to bias a complementary multiplier sub-structure. Such embodiments not only conserve bias current but also amplify the output signal, by doubling its magnitude. This method significantly improves the efficiency and effectiveness of the multiplier, addressing the key challenges in current analog multiplier design.

Embodiments described herein can reduce or minimize wasted current in traditional wide-range current multipliers by implementing a complementary multiplier sub-structure. This innovative approach allows for the reuse of bias currents from one multiplier sub-structure in another, effectively eliminating them from the output. This design not only enhances efficiency but may also optimize the overall performance of the system.

Certain embodiments eliminate current mirrors of certain traditional multiplier circuits. Some of these current mirrors copy both the signal and the bias currents leading to additional copies of the bias current flowing from a positive power rail to a negative power rail. An additional current mirror can subtract the negative output signal from the positive output signal to produce a bidirectional output current, beneficially removing bias currents from the output signal. However, if a differential output is desired, the positive and negative portions of the multiplication cannot be subtracted, leading to the bias current being included in the differential output currents. As a result, subsequent circuits, such as current buffers or current-to-voltage converters, must be designed to handle the larger combination of signal-plus-bias current. This can be exacerbated in high-frequency circuits where the bias current may be typically much larger than the signal current in the multiplier.

In high frequency circuits, where bias currents are notably large and hundreds of multipliers might be used in a single integrated circuit (IC), the power savings achieved through our invention can be substantial. For example, this reduction in power usage can directly translate to lower energy costs, which may be a significant factor in battery-powered electronic devices.

Such enhanced efficiency in power usage can potentially allow for a reduction in the size and complexity of power supply components while also improving power efficiency and extending the lifespan of the IC.

Embodiments described herein can recycle bias current from one multiplier sub-structure to be used to bias another. In some embodiments, the second multiplier sub-structure may be biased effectively without the need for an additional, separate bias current. Embodiments described herein can significantly enhance efficiency by using the bias currents that would otherwise be dissipated into the power rails. By redirecting bias currents to another multiplier, power is not only saved but the bias currents can contribute to an increase in the output signal's amplitude.

The wide range analog multipliers described herein multiply two inputs X and Y to produce an output OUT=X*Y. Additionally or alternatively, the multipliers use differential voltage signaling for the inputs. That is, multiplier inputs X and Y are encoded as voltages V_{x_p}, V_{x_n}, V_{y_p} and V_{y_n}, where differential voltage Vₓ=V_{x_p}−V_{x_n} is proportional to X, and differential voltage V_{y}=V_{y_p}−V_{y_n} is proportional to Y. The averages V_{x_c}=(V_{x_p}+V_{x_n})/2 and V_{y_c}=(V_{y_p}+V_{y_n})/2 are referred to as the common-mode, bias or reference levels, and are independent of the inputs X and Y. For positive values of X, V_{x_p}>V_{x_n} and since V_{x_c} is the average, V_{x_p}>V_{x_c}>V_{x_n}. For negative values of X, V_{x_p}<V_{x_c}<V_{x_n}. Similarly, for positive values of Y, V_{y_p}>V_{y_c}>V_{y_n}, and for negative values of Y, V_{y_p}<V_{y_c}<V_{y_n}.

The wide range analog multipliers described herein produce an output current Iₒᵤₜ proportional to OUT. In some embodiments, the output current is differential so that Iₒᵤₜ=L_{out_p}−I_{out_n}. The currents Lₒᵤₜ, I_{out_p}, and I_{out_n} can be bidirectional. That is, the currents can be negative or positive. For instance, if X and Y are of opposite sign, OUT will be negative and therefore Iₒᵤₜ may be negative also. The schematic diagrams show an arrow below the output current labels which indicate the direction of current flow for positive values of the bidirectional currents.

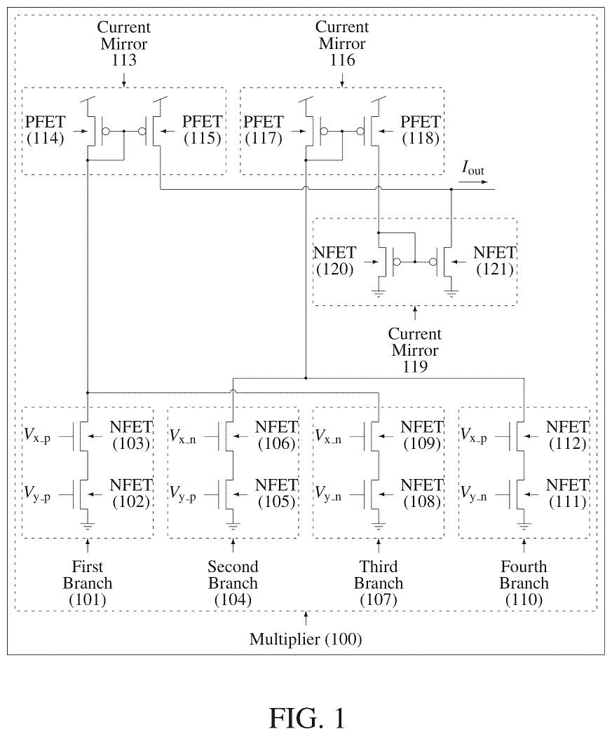

FIG. 1 shows an example analog multiplier 100, according to some embodiments. The analog multiplier 100 includes a plurality of current mirrors 113, 116, 119 and a plurality of branches 101, 104, 107, 110 of transistors. One or more of the current mirrors 113, 116, 119 and/or the branches 101, 104, 107, 110 can include two or more MOSFETs (Metal-Oxide-Semiconductor Field-Effect Transistors), such as n-channel MOSFETs (NFETs) and/or p-channel MOSFETs (PFETs). MOSFETs include transistors that can be used for amplifying and/or switching electronic signals. MOSFETs can operate by controlling a flow of current between source and drain terminals via a voltage applied to a gate terminal of the MOSFET.

The branches 101, 104, 107, 110 can each generate respective currents based on a multiplication of the differential component voltages applied to constituent MOSFETs. For example, the first branch 101 can generate a first current by multiplying V_{x_p} and V_{y_p}. This first current will be largest when inputs X and Y are in the first quadrant of the Cartesian plane (X>0 and Y>0), as this is when differential component voltages V_{x_p} and V_{y_p} are largest. However, due to the non-linear behavior of the transistors, the first current will be small in the three other quadrants of the Cartesian plane. Similarly, the second branch 104 generates a second current by multiplying V_{x_n} and V_{y_p} which is largest in the second quadrant of the Cartesian plane (X<0 and Y>0). The third branch 107 generates a third current by multiplying V_{x_n} and V_{y_n} which is largest in the third quadrant of the Cartesian plane (X<0 and Y<0). The fourth branch 110 generates a fourth current by multiplying V_{x_p} and V_{y_n} which is largest in the fourth quadrant of the Cartesian plane (X>0 and Y<0). Since the four generated currents are combined to produce the output current Iₒᵤₜ, each branch is responsible for its respective quadrant of the Cartesian plane, as the other branches will produce relatively small current contributions when the inputs are not in their preferred quadrant.

The first branch 101 can generate a current using NFET 103 controlled by V_{x_p} and NFET 102 controlled by V_{y_p}. The second branch 104 can generate a current using NFET 106 controlled by V_{x_n} and NFET 105 controlled by V_{y_p}. The third branch 107 can generate a current using a NFET 109 controlled by V_{x_n} and NFET 108 controlled by V_{y_n}. The fourth branch 110 can generate a current using a NFET 112 controlled by V_{x_p} and NFET 111 controlled by V_{y_n}.

Since the differential voltages Vₓ and V_{y} are proportional to the inputs X and Y, the product of the inputs is proportional to the product of the differential voltages. The product of Vₓ and V_{y_c}an be decomposed into Vₓ*V_{y}=(V_{x_p}*V_{y_p})−(V_{x_n}*V_{y_p})+(V_{x_n}*V_{y_n})−(V_{x_p}*V_{y_n}), where each of the four terms in the decomposition is mainly responsible for one quadrant of the Cartesian plane. Indeed, because the differential component voltages are positive (relative to the circuit ground), the V_{x_p}*V_{y_p} term will be largest in the first quadrant of the Cartesian plane, the V_{x_n}*V_{y_p} term will be largest in the second quadrant of the Cartesian plane, the V_{x_n}*V_{y_n} term will be largest in the third quadrant of the Cartesian plane, and the V_{x_p}*V_{y_n} term will be largest in the fourth quadrant of the Cartesian plane. Thus, the decomposition of the product Vₓ*V_{y} hints that the output of the multiplier should be generated by summing the currents from the first and third branches and subtracting the currents from the second and fourth branches.

The analog multiplier 100 can combine currents from the first branch 101 and the third branch 107 and pass the combined current to PFET 114 of the current mirror 113. Additionally or alternatively, the analog multiplier 100 can combine currents from the second branch 104 and the fourth branch 110 and pass the combined current to PFET 117 of the current mirror 116. The current mirrors 113 and 116 can include a diode connected input transistor (e.g., PFET 114 or PFET 117) to allow the current mirrors 113 and 116 to take in a current, convert it to a voltage, and then convert the voltage back to a current at the output transistor (e.g. PFET 115 or PFET 118). Current mirror 113 then passes its output current from PFET 115 directly to the output of the multiplier, while current mirror 116 passes its output current from PFET 118 to a third current mirror 119. Current mirror 119 includes a diode connected input transistor NFET 120, which converts the current from current mirror 116 into a voltage. This voltage is then converted back to a current by output transistor NFET 121. Current mirror 119 then passes its output current from NFET 121 directly to the output of the multiplier to be combined with the output current from mirror 113. The action of current mirror 119 reverses the direction of the output current from current mirror 116, so that when it is combined with the output current from current mirror 113, it results in a subtraction, as required by the multiplication. The action of current mirrors 113, 116 and 119 is to produce an output current which is the difference of the sum of the currents from the first and third branches 101, 107 and the sum of the currents from the second and fourth branches 104, 110, as suggested by the product decomposition.

It should be noted that the currents from each branch 101, 104, 107, 110 as shown are not directly proportional to the product of the differential component voltages that control them. Instead, the currents are non-linear and dependent on higher order terms (e.g., proportional to V_{y_p}² or V_{y_p}²*V_{x_p}) as well as linear terms (e.g., proportional to V_{x_p} or V_{y_p}). However, combining the currents from the four branches, as suggested by the decomposition, cancels out many of these undesirable terms. Other embodiments are possible.

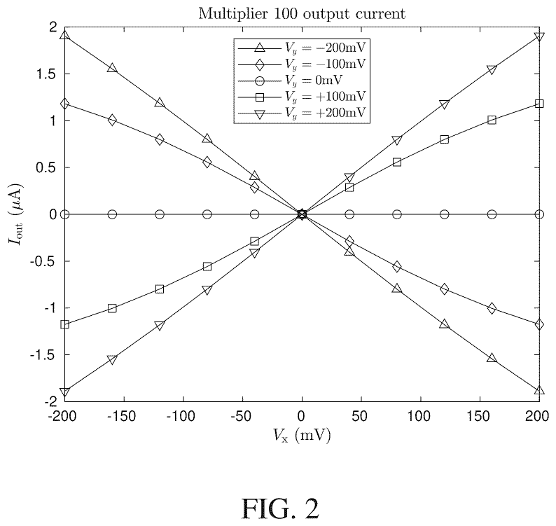

FIG. 2 shows a graph of the output current for one example embodiment of analog multiplier 100. Other embodiments of analog multiplier may differ through the use of, for example, different NFET and PFET transistors, different NFET and PFET dimensions, different bias conditions, different power supplies, or altogether different fabrication technologies, which can result in different graphs of the output current.

The current mirrors 113, 116, 119 can replicate (or “mirror”) a current from a connected branch of the circuit to another. For example, current mirrors 113, 116, 119 can help promote accurate current replication and/or scaling between the branches 101, 104, 107, 110, enabling a proper operation of the analog multiplier 100. In some embodiments, the number of mirrors can be reduced to just one, by eliminating current mirrors 116 and 119, and passing the combined currents from branches 104 and 110 directly to the multiplier output. However, in such embodiments this may result in branches 104 and 110 being connected to the output voltage, which may not be the same as the voltage that branches 101 and 107 are connected to (at the input of current mirror 113). This difference in voltage may cause an unequal application of the finite output conductance effect of transistors to the branch currents, potentially resulting in less precise multiplication results. The use of cascode transistors can mitigate this problem. Additionally or alternatively, using a plurality (e.g., three) of current mirrors, as shown in FIG. 1, can provide a wider tolerance to output voltages for the multiplier.

The current mirrors 113, 116, 119 may promote equivalent and/or proportional currents to be produced by the different branches 101, 104, 107, 110.

This can be beneficial because the accuracy of the multiplication may depend on maintaining a precise current relationships between the branches 101, 104, 107, 110. The current mirrors 113, 116, 119 can scale an applied current by a fixed ratio. This scaling may allow for control of different weightings of respective currents in the analog multiplier 100. For example, the current mirrors 113 and 116 may apply a first scaling factor to increase or decrease the multiplier output current. Additionally or alternatively, the multiplier may be constructed using additional branches (e.g., two or more branches per quadrant), where instead of combining branch currents at the input of one current mirror, multiple current mirrors are used to scale the currents from different branches by different amounts. This may be done, for example, in order to improve the multiplier's linearity or input range.

In analog multiplier 100, V_{y} controls NFET 102, NFET 105, NFET 108, and NFET 111, each of which are biased in the linear region due to V_{y}'s common mode voltage V_{y_c}. Vₓ controls NFET 103, NFET 106, NFET 109, and NFET 112, each of which are typically biased in the saturation region and behave as cascode devices. This allows both Vₓ and V_{y} to control the branch current, where V_{y} controls the gate terminal of the linear transistors and Vₓ essentially controls the drain terminal of the linear transistors.

The use of current mirrors 113, 116, 119 in analog multiplier 100 is to independently control the voltage at the drains of the multiplication cascode transistors (e.g., NFET 103, NFET 106, NFET 109, NFET 112). Adjustment of the operating mode and bias currents of these transistors can be controlled by the selection of the transistor sizes. Additionally or alternatively, the source voltage of NFET 102, NFET 105, NFET 108, and/or NFET 111 can be set to a voltage level other than ground. Additionally or alternatively, the analog multiplier 100 can adjust the power supply voltage to current mirrors 113 and 116 (e.g., source voltage of PFETs 114, 115, 117 and 117).

Although the use of current mirrors is beneficial to analog multiplier 100, they cause the circuit to dissipate additional power. This is because the current mirrors copy currents instead of reusing currents. For example, the current produced by PFET 118 of current mirror 116 goes only to NFET 120 of current mirror 119, resulting in a current that flows from the power supply to ground, and is not itself part of the output current. Additionally, the current produced by the four branches 101, 104, 107 and 110 can contain a bias current that is a by-product of the operation of the branches. These bias currents are canceled when the currents are subtracted at the output of the multiplier, but they still are copied by the current mirrors even though they are not part of the multiplier output current. These bias currents could be eliminated by adding offset currents at the inputs of current mirrors 113 and 116, but the current mirrors themselves need a bias current to operate, so that this is not a practical solution.

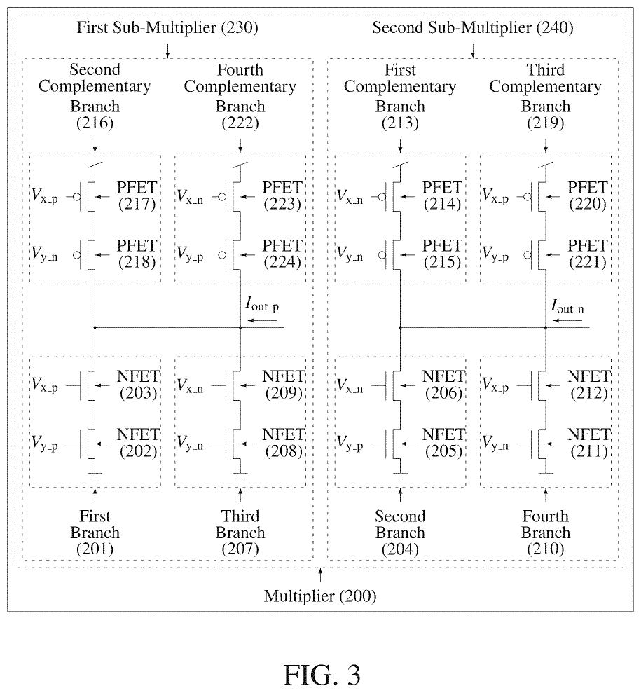

FIG. 3 shows another example analog multiplier 200, according to some embodiments. The analog multiplier 200 may achieve accurate and reliable results without the use of current mirrors. The analog multiplier 200 includes a first sub-multiplier 230 and a second sub-multiplier 240. Each of the first sub-multiplier 230 and the second sub-multiplier 240 include respective constituent branches. The first sub-multiplier 230 can include a first branch 201, a third branch 207, a second complementary branch 216, and a fourth complementary branch 222. The second sub-multiplier 240 can include a second branch 204, a fourth branch 210, a first complementary branch 213, and a third complementary branch 219. The analog multiplier 200 can generate a higher transimpedance than existing technologies, which may allow a more linear circuit, a greater output current, and/or other benefits.

The term “complementary” as used herein can adopt its plain and ordinary meaning of the term. In some contexts, a first meaning of the term “complementary” may refer to corresponding branches between the first sub-multiplier 230 and the second sub-multiplier 240 that contain opposite-valued MOSFETs and/or different MOSFETs. For example, as shown in FIG. 3, the first branch 201 and the first complementary branch 213 may be complementary to one another because the first branch 201 may use NFETs while the first complementary branch 213 may use PFETs. Additionally or alternatively, the first branch 201 and/or the first complementary branch 213 may both produce higher (e.g., the greatest) currents when the inputs X and Y are in the first quadrant of the Cartesian plane, but the current direction is opposite. Other meanings of the term are possible. As used with respect to FIG. 3, both meanings of the term “complementary” apply. However, in other contexts and/or in other embodiments, one or more different meanings of the term may be used.

The first sub-multiplier 230 and/or the second sub-multiplier 240 can generate independent multiplication results. One or more of the sub-multipliers 230, 240 can generate a set of currents corresponding to one of the four quadrants of the Cartesian plane. For example, the first branch 201 and the first complementary branch 213 may each generate currents corresponding to the first quadrant of the Cartesian plane. Additionally or alternatively, the second branch 204 and the second complementary branch 216 may each generate currents corresponding to the second quadrant of the Cartesian plane. The third branch 207 and the third complementary branch 219 may each generate currents corresponding to the third quadrant of the Cartesian plane. The fourth branch 210 and the fourth complementary branch 222 may each generate currents corresponding to the fourth quadrant of the Cartesian plane. In some embodiments, one or both of the first sub-multipliers 230, 240 include no more than four branches. Additionally or alternatively, one or more of the branches 201, 204, 207, 210, 213, 216, 219, 222 generate an electrical representation of a mathematical result each corresponding to respective target quadrants of a Cartesian plane.

The first branch 201 can be configured to multiply voltages V_{x_p} and V_{y_p} to obtain a first current. The second complementary branch 216 can be configured to multiply voltages V_{x_p} and V_{y_n} to obtain a second complementary current. The third branch 207 may be configured to multiply voltages V_{x_n} and V_{y_n} to obtain a third current. The fourth complementary branch 222 may be configured to multiply voltages V_{x_n} and V_{y_p} to obtain a fourth current. The first sub-multiplier 230 can summate the first, second complementary, third, and fourth complementary currents. Noting that the second complementary and fourth complementary currents are of opposite direction from the first and third currents, the resulting current follows the product decomposition of Vₓ*V_{y}. The resulting current may be labeled I_{out_p}.

With respect to the second sub-multiplier 240, the first complementary branch 213 can be configured to multiply voltages V_{x_n} and V_{y_n} to obtain a first complementary current (e.g., complementary to the first current value generated by the first branch 201). The second branch 204 can be configured to multiply voltages V_{x_n} and V_{y_p} to obtain a second current. The third complementary branch 219 can be configured to multiply voltages V_{x_p} and V_{y_p} to obtain a third complementary current. The fourth branch 210 can be configured to multiply voltages V_{x_p} and V_{y_n} to obtain a fourth current. The second sub-multiplier 240 can summate the first complementary, second, third complementary, and fourth currents. Noting that the first complementary and third complementary currents are of opposite direction from the second and fourth currents, the resulting current follows the product decomposition of Vₓ*V_{y}. The resulting current may be labeled I_{out_n} and is complementary to I_{out_p}.

In some embodiments, I_{out_p} and I_{out_n} may be the component currents of a differential current Iₒᵤₜ. That is, Iₒᵤₜ=I_{out_p}−I_{out_n} and I_{out_c}=(I_{out_p}+I_{out_n})/2, where I_{out_c} is a bias or common mode current level (which may be zero, positive or negative). Thus, a difference between the I_{out_p} and the I_{out_n} may result in a current signal value that has a magnitude that is double that of either of I_{out_p} or the I_{out_n}. When I_{out_c} is zero, I_{out_p} and I_{out_n} are equal in magnitude but of opposite sign, and this condition maximizes the branch bias current reuse. However, having a small positive or negative value for I_{out_c} is not unusual, and may not impact the performance of the circuit. Larger positive or negative values of I_{out_c} can also be useful in cases where I_{out_p} and I_{out_n} are flowing to another circuit that is not capable of handling bidirectional currents (e.g. current mirrors).

In some embodiments, the various branches or groups of branches of the analog multiplier 200 may be configured to provide electrical bias to other(s) of the branches of the analog multiplier 200. For example, the current produced by the first branch 201 and the third branch 207 which does not flow to the output I_{out_p} can be considered to be a bias current. The current produced by the second complementary branch 216 and the fourth complementary branch 222 which does not flow to the output I_{out_p} can also be considered to be the same bias current. Thus the bias current from one pair of branches is reused by another pair.

The additional eight transistors (the PFET 217, the PFET 218, the PFET 223, the PFET 224, the PFET 214, the PFET 215, the PFET 220, the PFET 221) can be of the opposite type of those in the analog multiplier 100. In the embodiment shown, they are PFET transistors. In some embodiments where the transistors of the first branch 201, the second branch 204, the third branch 207, and the fourth branch 210 are PFET transistors, then these additional transistors (in the first complementary branch 213, the second complementary branch 216, the third complementary branch 219, and the fourth complementary branch 222) would be NFET. In the analog multiplier 200, the PFET 217, the PFET 223, the PFET 214, and the PFET 220 are controlled by the input voltage Vₓ and PFET 218, the PFET 224, the PFET 215, and the PFET 221 are controlled by V_{y}. This simplifies the case where the common-mode voltages V_{x_c} and V_{y_c} are different. In other embodiments, the connections are reversed, and the circuit may need different common-mode voltages for the complementary branches than for the original branches.

The complementary transistors (e.g., the transistors of the complementary branches 213, 216, 219, 222) are connected to the corresponding original transistors (e.g., the transistors of the branches 201, 204, 207, 210, which are similar to the transistors in branches 101, 104, 107 and 110 of multiplier 100) in a manner that facilitates logical subtraction of the multiplication currents. For example, the currents from transistors in the first and third branches 201, 207, which contributed to the positive portion of the multiplication output in the analog multiplier 100, are counterbalanced in the analog multiplier 200 by the currents from transistors in the second and fourth complementary branches 216, 222. This counterbalancing can include the biasing effect disclosed herein. The transistors in the second and fourth complementary branches 216, 222 are configured to produce a negative contribution to the multiplication output relative to the contribution of the transistors in the first and third branches 201, 207. Additionally or alternatively, the currents from transistors of the second and fourth branches 204, 210, which correspond to the transistors responsible for the negative portion of the output of the analog multiplier 100, are offset by the currents from the transistors of the first and third complementary branches 213, 219.

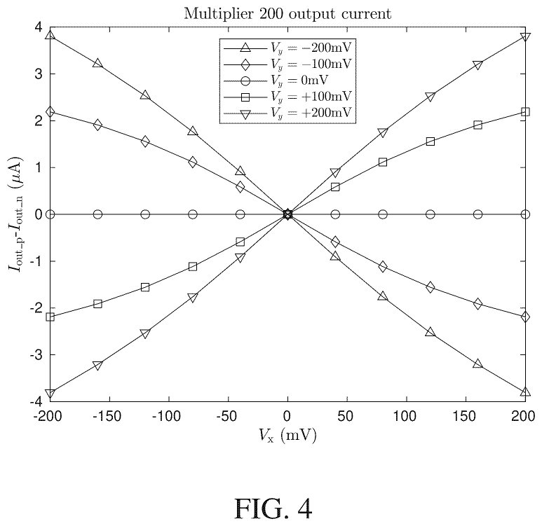

FIG. 2 and FIGS. 4-6 show graphs of total output current of some of the multiplier embodiments described herein, versus different voltage values (Vₓ) corresponding to values representing the first input X for five different voltage values of the second input Y (V_{y}). In all figures, the input voltage Vₓ is swept from −200 mV to +200 mV, and V_{y} is stepped through values −200 mV, −100 mV, 0V, +100 mV, and +200 mV. Comparing FIG. 2 and FIG. 4, while the outputs characteristics of both multipliers 100, 200 are nearly identical in shape and behavior, the output current from the analog multiplier 200 disclosed in FIG. 3 is nearly twice that from the analog multiplier 100 in FIG. 1.

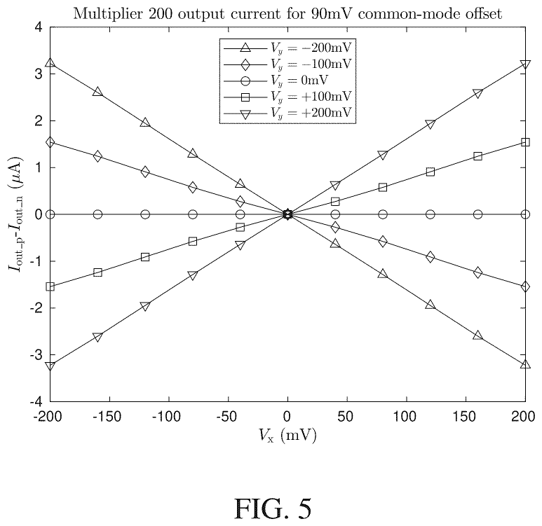

FIG. 5 shows a graph of output current Iₒᵤₜ of the analog multiplier 200 shown in FIG. 3, but with V_{x_c} greater than V_{y_c} by 90 mV. The additional 90 mV provides greater headroom for the operation of the cascode and linear transistors in the various branches of the multiplier. This results in improved linearity compared to the graph in FIG. 4 (where V_{x_c}=V_{y_c}). Note that the best common-mode offset voltage is dependent on various factors such as, for example, the transistor types, transistor sizes, power supply or fabrication technology.

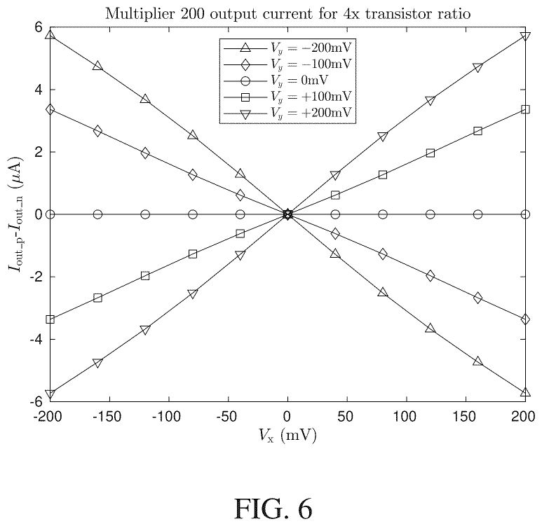

FIG. 6 shows a graph of output current Iₒᵤₜ of the analog multiplier 200 shown in FIG. 3, but with the cascode transistor four times wider than the linear transistors, in order to provide greater headroom. The improvement in linearity is not as good as the graph shown in FIG. 5, but as the results are dependent on many factors, in some embodiments, altering the transistor ratio may have a greater beneficial effect than altering the common-mode offset voltage.

The possible configurations should be not be limited to the embodiments illustrated herein. For example, in some embodiments, additional parallel branches with different size transistors can be included, the power supply voltage can be increased or decreased (e.g., by adjusting either the source voltage of the NFET devices or the source voltage of the PFET devices), or the ratio of the PFET device sizes relative to the NFET device sizes can be adjusted. These changes can affect the graph of the output current also, and may be chosen to improve linearity or decrease power consumption.

Note that the graphs in FIGS. 4-6 plot I_{out_p}−I_{out_n}=Iₒᵤₜ. Although the component currents I_{out_p} and I_{out n} themselves are generated by sub-multipliers (e.g. sub-multiplier 230 and 240), each component current is not always linear as a function of the inputs X and Y. This is because the cancellation of the higher order terms and the linear terms may not be complete due to the typical mismatch in characteristics between NFET and PFET devices.

While the power consumption patterns of both analog multipliers 100, 200 are similar, the power consumed by the analog multiplier 200 will generally be less than or equal to the power consumed by the analog multiplier 100. This is due to the fact that both multipliers 100, 200 use the same design for the NFET branches. The PFET branches in analog multiplier 200 should not add to the power consumption as they pass the current that would normally flow into current mirrors 113 and 116 of multiplier 100. However, the elimination of current mirror 119 (if used in multiplier 100) will generally not result in a power reduction.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

1. A four-quadrant analog multiplier comprising:
a first branch configured to multiply voltage values representing a positive x-value, relative to an x-reference voltage, and a positive y-value, relative to a y-reference voltage, to obtain a first branch current;
a second branch configured to multiply voltage values representing the positive x-value, relative to the x-reference voltage, and a negative y-value, relative to the y-reference voltage, to obtain a second branch current;
a third branch configured to multiply voltage values representing a negative x-value, relative to the x-reference voltage, and the negative y-value, relative to the y-reference voltage, to obtain a third branch current; and
a fourth branch configured to multiply voltage values representing the negative x-value, relative to the x-reference voltage, and the positive y-value, relative to the y-reference voltage, to obtain a fourth branch current;
wherein the four-quadrant analog multiplier is configured to summate the first, second, third, and fourth branch currents to generate a first output current; and
wherein at least one of the first, second, third, or fourth branches comprises a PFET, and wherein at least one of the first, second, third, or fourth branches comprises an NFET.

2. The four-quadrant analog multiplier of claim 1, further comprising:
a fifth branch configured to multiply voltage values representing the positive x-value, relative to an x-reference voltage, and a positive y-value, relative to a y-reference voltage, to obtain a fifth branch current;
a sixth branch configured to multiply voltage values representing the positive x-value, relative to the x-reference voltage, and a negative y-value, relative to the y-reference voltage, to obtain a sixth branch current;
a seventh branch configured to multiply voltage values representing a negative x-value, relative to the x-reference voltage, and the negative y-value, relative to the y-reference voltage, to obtain a branch seventh current; and
an eighth branch configured to multiply voltage values representing the negative x-value, relative to the x-reference voltage, and the positive y-value, relative to the y-reference voltage, to obtain an eighth branch current;
wherein the four-quadrant analog multiplier is configured to summate the fifth, sixth, seventh, and eighth branch currents to generate a second output current.

3. The four-quadrant analog multiplier of claim 2, wherein at least one of the fifth, sixth, seventh, or eighth branches comprises a PFET, and wherein at least one of the fifth, sixth, seventh, or eighth branches comprises an NFET.

4. The four-quadrant analog multiplier of claim 2, wherein a magnitude, relative to a reference current, of the first output current is configured to be equal to a magnitude, relative to the reference current, of the second output current.

5. The four-quadrant analog multiplier of claim 2, wherein the four-quadrant analog multiplier is configured to generate a difference between the first output current and the second output current.

6. The four-quadrant analog multiplier of claim 1, wherein at least one of the second or fourth branches is configured to electrically bias at least one of the first or third branches.

7. The four-quadrant analog multiplier of claim 1, wherein each of the first, second, third, and fourth branches is configured to contribute to generating a multiplication result corresponding to a respective target quadrant of a Cartesian plane.

8. The four-quadrant analog multiplier of claim 2, wherein a first reference branch, selected from the group consisting of the first, second, third, and fourth branches, and a second reference branch, selected from the group consisting of the fifth, sixth, seventh, and eighth branches, are each configured to contribute to generating a multiplication result corresponding to a same target quadrant of a Cartesian plane.

9. An analog multiplier comprising:
a first multiplier comprising a first plurality of PFETs and a first plurality of NFETs, the first multiplier configured to receive at least four voltages and configured to output, based on the at least four voltages, a first output current; and
a second multiplier comprising a second plurality of PFETs and a second plurality of NFETs, the second multiplier configured to receive the at least four voltages and configured to output, based on the at least four voltages, a second output current.

10. The analog multiplier of claim 9, wherein a magnitude, relative to a reference current, of the first output current is configured to be equal to a magnitude, relative to the reference current, of the second output current.

11. The analog multiplier of claim 9, wherein the analog multiplier is configured to generate a difference between the first output current and the second output current.

12. The analog multiplier of claim 9, wherein the first multiplier comprises at least four branches, wherein each of the at least four branches is configured to generate an electrical representation of a mathematical result each corresponding to respective target quadrants of a Cartesian plane.

13. The analog multiplier of claim 12, wherein the second multiplier comprises at least four other branches, wherein each of the at least four other branches is configured to generate an electrical representation of a mathematical result each corresponding to a respective quadrant of the target quadrants of the Cartesian plane.

14. The analog multiplier of claim 9, wherein at least one branch of the first multiplier is configured to electrically bias at least one other branch of the first multiplier.

15. The analog multiplier of claim 9, wherein at least one branch of each of the first and second plurality of branches is configured to contribute to generating a multiplication result corresponding to a same target quadrant of a Cartesian plane.

16. An analog multiplier comprising:
a first multiplier configured to output a first output current, the first multiplier comprising a first plurality of branches each configured to generate respective branch currents of a first plurality of branch currents, the first multiplier configured to summate the first plurality of branch currents to generate the first output current; and
a second multiplier configured to output a second output current, the second multiplier comprising a second plurality of branches each configured to generate respective branch currents of a second plurality of branch currents, the second multiplier configured to summate the second plurality of branch currents to generate the second output current.

17. The analog multiplier of claim 16, wherein a magnitude, relative to a reference current, of the first output current is configured to be equal to a magnitude, relative to the reference current, of the second output current.

18. The analog multiplier of claim 16, wherein each of the first plurality of branches is configured to contribute to generating a set of electrical representations of mathematical results corresponding to respective target quadrants of a Cartesian plane.

19. The analog multiplier of claim 18, wherein each of the second plurality of branches is configured to contribute to generating the set of electrical representations of the mathematical results corresponding to respective quadrants of the target quadrants of the Cartesian plane.

20. The analog multiplier of claim 16, wherein at least one branch of the first multiplier is configured to electrically bias at least one other branch of the first multiplier.
